(19) United States
(12) Patent Application Publication
(10) Pub. No.: US 2010/0220270 A1
(43) Pub. Date: Sep. 2, 2010

(54) METHOD FOR FORMING REFLECTION ELECTRODE, DRIVE SUBSTRATE, AND DISPLAY DEVICE

(75) Inventors: Hirotsugu Ishihara, Tokyo (JP); Masanobu Tanaka, Kanagawa (JP); Toshiki Shimamura, Kanagawa (JP); Takahiro Kamei, Kanagawa (JP)

Correspondence Address: K&L Gates LLP, P. O. BOX 1135, CHICAGO, IL, 60690, US

(73) Assignee: SONY CORPORATION, Tokyo (JP)

(21) Appl. No.: 12/707,869

(22) Filed: Feb. 18, 2010

(30) Foreign Application Priority Data
Feb. 27, 2009 (JP) P2009-046626

(51) Int. Cl. G02F 1/1335; H05K 1/09; H01M 4/88

(52) U.S. Cl. 349/113; 174/256; 502/101

(57) ABSTRACT

A method for forming a reflection electrode is provided which includes the steps of: forming a first catalytic layer in a first region of an electrode forming region of a substrate; forming a first plating layer on the first catalytic layer by performing a first electroless plating treatment; forming a second catalytic layer at least in a region (second region) of the electrode forming region other than the first region; and forming a second plating layer on the second catalytic layer by performing a second electroless plating treatment, so that the reflection electrode is formed to have a concave-convex surface.

### CROSS REFERENCES TO RELATED APPLICATIONS

The present application contains subject matter related to that disclosed in Japanese Priority Patent Application JP 2009-046626 filed in the Japan Patent Office on Feb. 27, 2009, the entire content of which is hereby incorporated by reference.

### BACKGROUND

The present application relates to a method for forming a reflection electrode used for a display device, such as a liquid crystal display device, and to a drive substrate and a display device, each of which includes the reflection electrode.

In the present days, in a reflection type liquid crystal device used for a mobile apparatus or the like, unlike a transmissive liquid crystal device including a so-called backlight, a display is performed using light incident from the surrounding environment. Accordingly, it is necessary to reflect light incident from the surrounding environment to an observer side while the loss of the light is decreased as low as possible.

As a reflection layer used in the reflection type liquid crystal device, for example, an intra-LCC (liquid crystal cell) diffuse reflection plate method, an extra-LCC reflection plate method, and a forward scattering reflection plate method have been used, and among those mentioned above, the intra-LCC diffuse reflection plate method has been frequently used because of its significantly superior display characteristics.

A reflection electrode used in this intra-LCC diffuse reflection plate method can be obtained when a metal thin film of aluminum (Al), silver (Ag), or the like, which is used as a pixel electrode, is formed to have a concave-convex surface. In particular, the following method may be mentioned. That is, for example, after thin film transistors (TFTs) are formed on a substrate, an interlayer insulating film is formed on the TFTs, and after the surface of this interlayer insulating film is patterned by a photolithographic method, a concave-convex shape is formed by performing a heat treatment. Subsequently, a metal thin film to be formed into reflection electrodes is formed over the entire surface of the substrate by vacuum film formation and is then patterned by a photolithographic method (see Japanese Patent Nos. 3895059 and 3866522). In addition, the following method may also be used. In this method, after TFTs are formed on a substrate, a resin film is formed on the TFTs with an interlayer insulating film interposed therebetween, the resin film thus formed is patterned into a stripe shape by a photolithographic method, and a heat treatment is performed to deform the resin film thus patterned. Subsequently, after a resin is further applied on the deformed resin film to form a smooth concave-convex surface, a metal thin film to be formed into reflection electrodes is formed over the entire surface of the substrate by vacuum deposition, and this metal thin film is patterned by a photolithographic method (Japanese Unexamined Patent Application Publication No. 2002-229060).

Compared to a method in which an electrode surface is directly roughened by a sandblast method or the like and to a method in which after silicon dioxide (SiO₂) or the like is taper-etched, a metal thin film is formed, the methods described above each have an advantage in that no process damage is done to the elements. In addition, since a smooth concave-convex shape can be easily controlled, the methods described above have been widely used.

### SUMMARY

However, according to the methods described above, a photolithographic method using a resist (photosensitive resin) material is necessarily used in order to control the shape of the interlayer insulating film and to pattern the metal film after the formation thereof, and as a result, the number of steps is disadvantageously increased in the methods described above.

The present application has been conceived in consideration of the problem described above, and it is desirable to provide a method for forming a reflection electrode by a simple process, and a drive substrate and a display device, each of which uses the reflection electrode described above.

In accordance with an embodiment of the present application, there is provided a method for forming a reflection electrode which includes the following steps (A1) to (D1). That is, the method includes a step (A1) of forming a first catalytic layer in a first region of an electrode forming region of a substrate; a step (B1) of forming a first plating layer on the first catalytic layer by performing a first electroless plating treatment; a step (C1) of forming a second catalytic layer at least in a region (second region) of the electrode forming region other than the first region; and a step (D1) of forming a second plating layer on the second catalytic layer by performing a second electroless plating treatment, so that the reflection electrode is formed to have a concave-convex surface.

In accordance with an embodiment of the present application, there is provided a drive substrate including a substrate which has a reflection electrode having a concave-convex surface in an electrode forming region, and the reflection electrode has a first catalytic layer (A2) provided in a first region of the electrode forming region; a first plating layer (B2) provided on the first catalytic layer; a second catalytic layer (C2) provided at least in a region (second region) of the electrode forming region other than the first region; and a second plating layer (D2) provided on the second catalytic layer.

In accordance with an embodiment of the present application, there is provided a display device which includes a drive substrate having reflection electrodes provided in electrode forming regions; and a display portion which performs a display using incident light reflected by the reflection electrodes.

In the display device described above, light incident from the outside is efficiently reflected by concave-convex portions of the reflection electrodes each formed of the first and the second plating layers and is then sent to a side of the display portion, such as a liquid crystal layer; hence, a display is performed.

In the method for forming a reflection electrode according to an embodiment of the present application, after the first plating layer is formed by selectively performing the first electroless plating treatment on the first region of the electrode forming region on the substrate, the second electroless plating treatment is performed on the remaining second region; hence, a reflection electrode having a concave-convex shape can be formed in a desired region. Accordingly, compared to a related case in which a photolithographic method is used, the reflection electrode can be formed by simple steps. In addition, the usage amount of a photosensitive resin can be reduced, and hence cost can be reduced. As a result, by using the method described above, an inexpensive drive substrate and an inexpensive display device can be realized.

Additional features and advantages are described herein, and will be apparent from the following Detailed Description and the figures.

### BRIEF DESCRIPTION OF THE FIGURES

FIG. 1 is a cross-sectional view showing the structure of a display device according to a first embodiment of the present application;

FIGS. 2A to 2E are cross-sectional views showing sequential steps of forming a reflection electrode shown in FIG. 1;

FIGS. 3A to 3D are cross-sectional views showing steps following the step shown in FIG. 2E;

FIGS. 4A and 4B are cross-sectional views showing steps following the step shown in FIG. 3D;

FIG. 5 is a cross-sectional view showing a step of forming a reflection electrode according to a second embodiment of the present application;

FIGS. 6A and 6B are cross-sectional views showing steps of forming a reflection electrode according to a third embodiment of the present application;

FIGS. 7A and 7B are cross-sectional views showing steps of forming a reflection electrode according to a fourth embodiment of the present application;

FIGS. 8A to 8C are views each showing an example of a formation region of a catalytic layer;

FIG. 9 is a view showing one example of a metal pattern formed by patterning;

FIG. 10A is a view showing a step structure (A) formed by a method for forming a reflection electrode according to an embodiment of the present application;

FIG. 10B is a view showing a related step structure (B) formed by using a photolithographic method;

FIGS. 11A to 11D are cross-sectional views showing sequential steps of forming a reflection electrode according to Comparative Example 1; and

FIGS. 12A to 12C are cross-sectional views showing sequential steps of forming a reflection electrode according to Comparative Example 2.

### DETAILED DESCRIPTION

The present application will be described with reference to the drawings according to an embodiment.

1. First embodiment

(1) Whole structure of a liquid crystal display device.

(2) Formation method 1 of a reflection electrode (an example in which a second catalytic layer is provided between a first plating layer and a second plating layer.)

2. Second embodiment (an example in which a second catalytic layer is not provided between a first plating layer and a second plating layer.)

3. Third embodiment (an example in which a third plating layer (Ag layer) is provided.)

4. Fourth embodiment (the same as that of the third embodiment.)

### First Embodiment

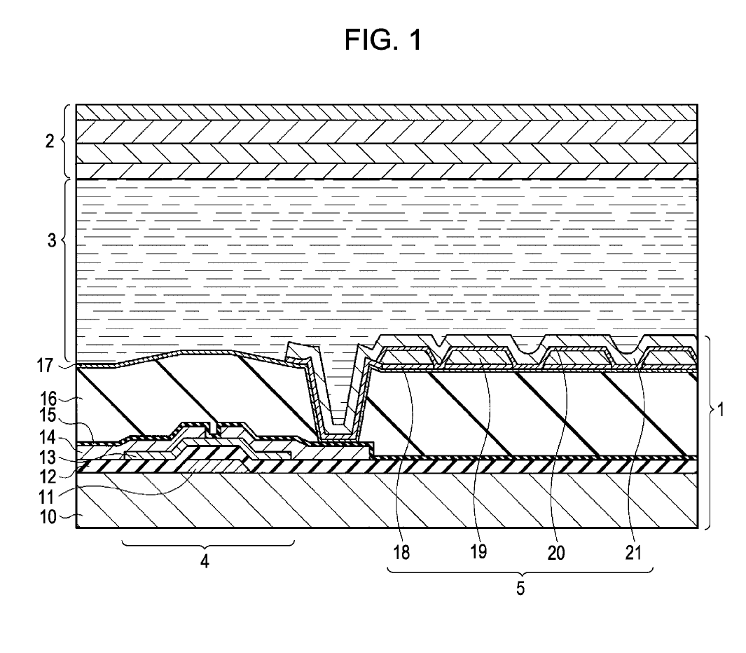

FIG. 1 is a cross-sectional structure of a liquid crystal display device of an intra-LCC diffuse reflection plate method according to a first embodiment of the present application. In this liquid crystal display device, a liquid crystal layer 3 is provided between a drive substrate 1 and a counter substrate 2. The drive substrate 1 includes a substrate 10, active matrix elements 4 each including an a-Si TFT of an inversely-staggered structure, and reflection electrodes 5, the active matrix elements 4 and the reflection electrodes 5 being provided on the substrate 10.

In more particular, a gate electrode 11, a gate insulating film 12, a semiconductor layer (channel) 13, source/drain electrodes 14 are formed on the substrate 10 in that order, and a protective film 15 and an interlayer insulating film 16 are formed on the source/drain electrodes 14. A contact hole 16A is formed in the interlayer insulating film 16, and each reflection electrode 5 is formed in the contact hole 16A (the bottom portion and sidewall thereof) and on the interlayer insulating film 16 with an adhesive layer 17 interposed therebetween. In this embodiment, the reflection electrode 5 is formed by using an electroless plating method as described below and includes a first catalytic layer 18, a first plating layer 19, a second catalytic layer 20, and a second plating layer 21.

The substrate 10 is formed, for example, from silicon, synthetic quartz, glass, metal, resin, or a resin film. The gate electrode 11 is formed from chromium (Cr), molybdenum (Mo), or the like, and the gate insulating film 12 is formed from silicon oxide (SiOx), silicon nitride (SiNx), or the like. The semiconductor layer 13 is formed from a semiconductor material such as amorphous silicon (a-Si), and the source/drain electrodes 14 are formed from a metal material, such as aluminum (Al). The protective film 15 is formed from an insulating material such as silicon nitride (SiNx). Although the interlayer insulating film 16 is formed from SiNx or the like as in the case of the gate insulating film 12, any material may also be used as long as it has, for example, a low dielectric constant, heat resistance, a mechanical strength, and an effect of preventing diffusion of a wire metal.

The adhesive layer 17 is a layer to enhance the adhesion of the first catalytic layer 18 and the second catalytic layer 20 to the interlayer insulating film 16. As a material forming this adhesive layer 17, for example, there may be mentioned a silane coupling agent containing at least one selected from an amino-based silane compound, a mercapto-based silane compound, a phenyl-based silane compound, an alkyl-based silane compound, and the like. As the adhesive layer 17, an appropriate compound may be selected in accordance with materials forming the first catalytic layer 18, the second catalytic layer 20, and the interlayer insulating film 16. In addition, as the silane coupling agent, in particular, for example, KBM-603 (trade name) (N-2(aminoethyl)-3-aminopropyltrimethoxysilane) manufactured by Shin-Etsu Chemical Co., Ltd. may be used.

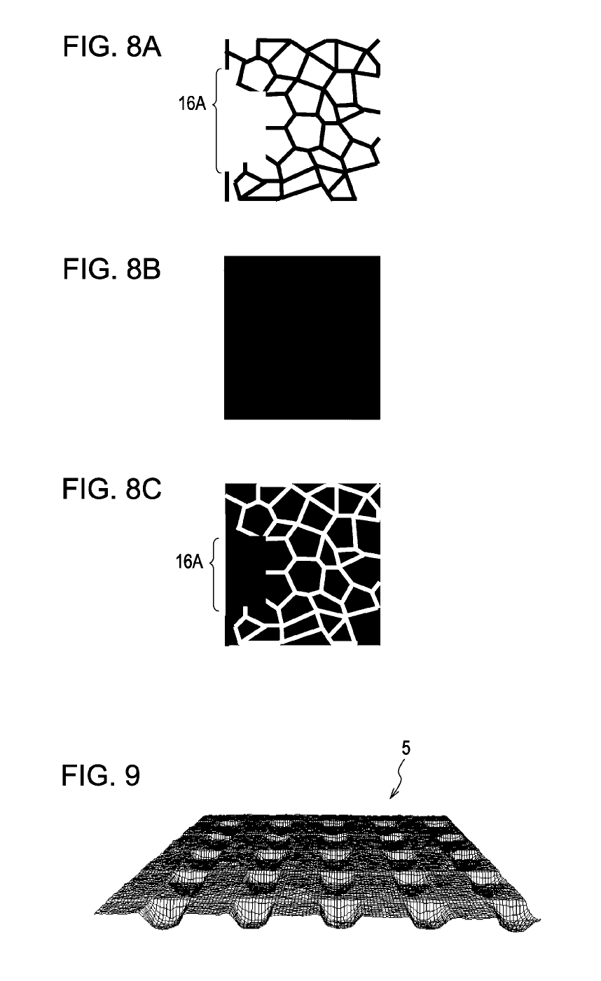

In this embodiment, the surface of the interlayer insulating film 16 and an inside area of the contact hole 16A are used as an electrode forming region, and in this electrode forming region, the reflection electrode 5 having a concave-convex surface is formed. The first catalytic layer 18 of the reflection electrode 5 is provided on the interlayer insulating film 16 to form a predetermined pattern. Although the cross-sectional shape of this first catalytic layer 18 is divided into a plurality of segments, the plan shape has, for example, a mesh pattern as shown in FIG. 8A. This pattern shape may be arbitrarily selected, and for example, a stripe pattern or a dispersed island pattern may also be used. In addition, in the electrode forming region, a region in which the pattern of the first catalytic layer 18 is formed is called a first region, and a region other than the first region is called a second region.

The thickness of the first catalytic layer 18 is, for example, approximately several to ten nanometers. When the patterning accuracy, the adhesion to the adhesive layer 17, and the usage amount of the material are taken into consideration, the thickness of the first catalytic layer 18 is preferably decreased as long as it functions as an electroless plating catalyst. The second catalytic layer 20 is formed on the first plating layer 19 provided on the interlayer insulating film 16 and on the adhesive layer 17 in the region (second region) other than the first region of the first catalytic layer 18 as in the case of the first catalytic layer 18. The first catalytic layer 18 and the second catalytic layer 20 each include at least one catalytic material selected from palladium (Pd), gold (Au), platinum (Pt), silver (Ag), and the like, used for an electroless plating treatment which will be describe later.

The first plating layer 19 is a layer grown on the patterned first catalytic layer 18 and has a thickness, for example, of approximately several tens to several hundreds of nanometers. The second plating layer 21 is formed so as to cover the first plating layer 19 formed on the first catalytic layer 18 and the second catalytic layer 20 and has a thickness, for example, of several hundreds of nanometers. The first plating layer 19 and the second plating layer 21 are plating layers each deposited by the electroless plating treatment which will be described later.

As an electroless plating material forming the first plating layer 19 and the second plating layer 21 described above, for example, a single metal, such as nickel (Ni), copper (Cu), gold (Au), silver (Ag), palladium (Pd), cobalt (Co), platinum (Pt), indium (In), tin (Sn), or rhodium (Rd), may be used. In addition, a metal which can generate a eutectic form with the metal mentioned above, such as phosphorous (P), boron (B), chromium (Cr), manganese (Mg), iron (Fe), zinc (Zn), molybdenum (Mo), cadmium (Cd), tungsten (W), rhenium (Re), titanium (Ti), sulfur (S), or vanadium (V), may also be used.

However, materials forming the first plating layer 19 and the second plating layer 21 are appropriately selected in association with materials forming the first catalytic layer 18 and the second catalytic layer 20, each of which functions as a catalyst of the electroless plating treatment.

In addition, the structure of the reflection electrode 5 as described above can be easily identified by one of the following methods (1) to (5).

(1) A cross-sectional shape of the reflection electrode 5 is observed, for example, by a scanning electron microscope (SEM).

(2) A cross section of the reflection electrode 5 is observed, for example, by a transmission electron microscope (TEM) to detect a catalytic material (the first catalytic layer 18 and the second catalytic layer 20) of the electroless plating treatment.

(3) Whether a metal capable of generating a eutectic form is included in the reflection electrode 5 or not is detected, for example, by secondary ion-microprobe mass spectrometry (SIMS) or x-ray photoelectron spectroscopy (XPS). For example, when the first plating layer 19 and the second plating layer 21 are formed to include nickel, it is also detected whether boron and/or phosphorous is contained or not.

(4) Whether an additive, such as an organic compound, used for the electroless plating treatment is included in the reflection electrode 5 or not is detected, for example, by SIMS.

(5) The roughness of the surface is observed, for example, by an atomic force microscope (AFM) or a stylus meter. However, when any type of surface treatment is performed after the electroless plating treatment, the evaluation is difficult to perform.

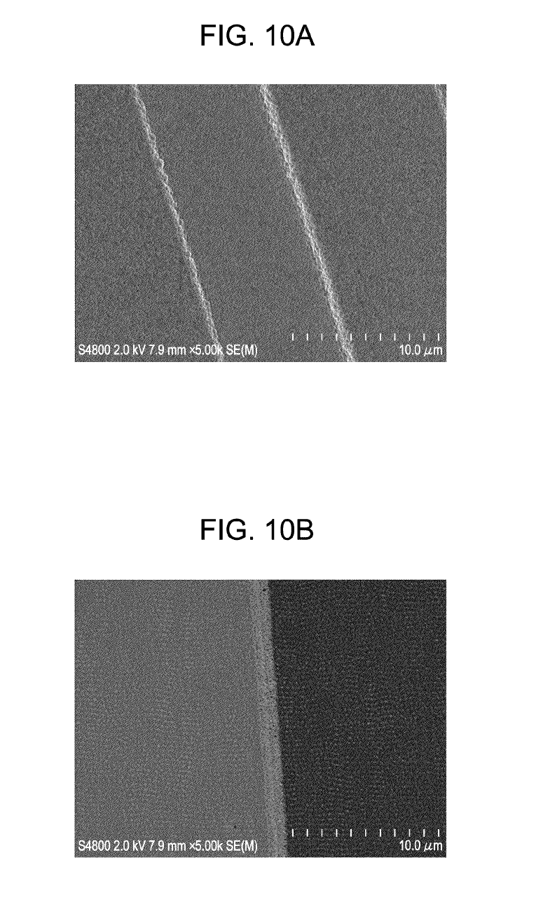

For example, FIG. 9 shows a simulation of one example of a metal pattern of the reflection electrode 5 of this embodiment. In addition, FIG. 10A is a SEM photograph showing a step structure formed by the two-stage plating method according to this embodiment, and FIG. 10B is a SEM photograph showing a step structure obtained by forming a plating layer, followed by patterning using photolithography and etching. In FIG. 10A, although the side surface of the step is formed of a continuous film extending from the upper portion, it is found in FIG. 10B that the etched side surface is not continuous from the surface of the upper portion.

The counter substrate 2 includes, for example, a polarizer 23, a retardation film 24, a color filter 25, and a transparent electrode (common electrode) 26 on a glass substrate 22.

[Manufacturing Method]

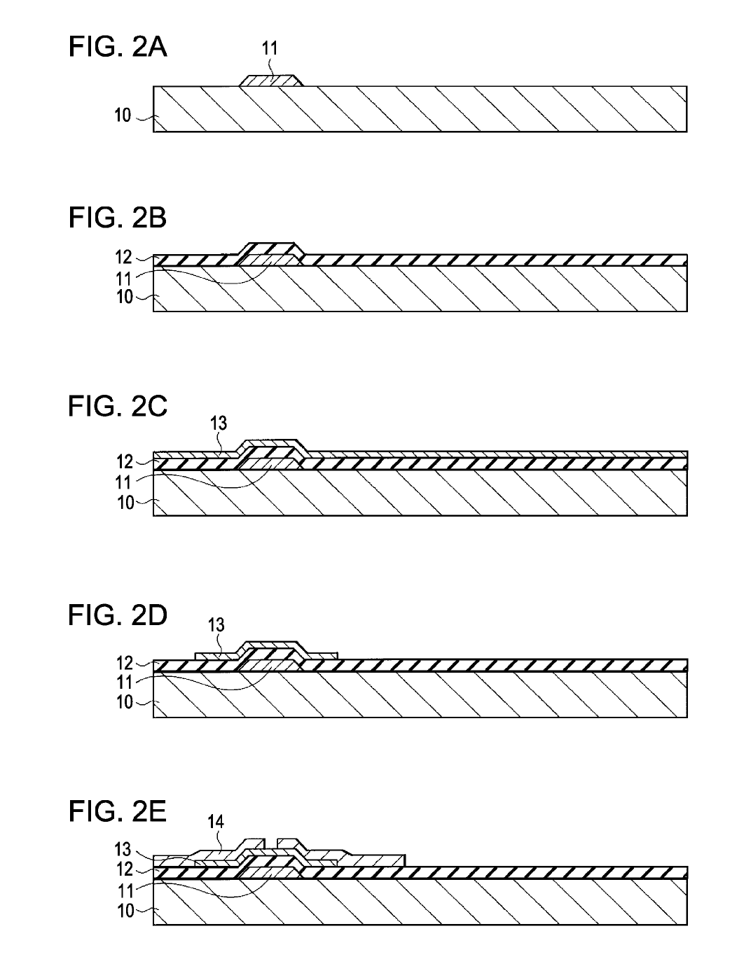

Next, a method for manufacturing the drive substrate 1 including the reflection electrode 5 will be described with reference to FIGS. 2A to 5.

(1. Formation of a TFT)

First, as shown in FIG. 2A, a film of a metal, such as Cr or Mo, is formed by a sputtering method or the like on the substrate 10 made of the aforementioned material, and this metal film is patterned by a photolithographic method, so that the gate electrode 11 is formed.

Subsequently, as shown in FIGS. 2B to 2E, after the gate insulating film 12 of SiNx or the like is formed, an a-Si layer to be formed into the channel and an n+ a-Si layer to be formed into contact layers (not shown) to be contact with the source/drain electrodes 14 are continuously formed as the semiconductor layer 13. Next, this semiconductor layer 13 is patterned to form an island shape by etching using a resist mask. Furthermore, after a film of a metal, such as Al, to be formed into the source/drain electrodes 14 is formed by a vacuum process, this metal film is patterned into a desired shape by etching using a resist mask, so that the source/drain electrodes 14 of a TFT are formed.

(2. Formation of the Interlayer Insulating Film 16 and the Adhesive Layer 17)

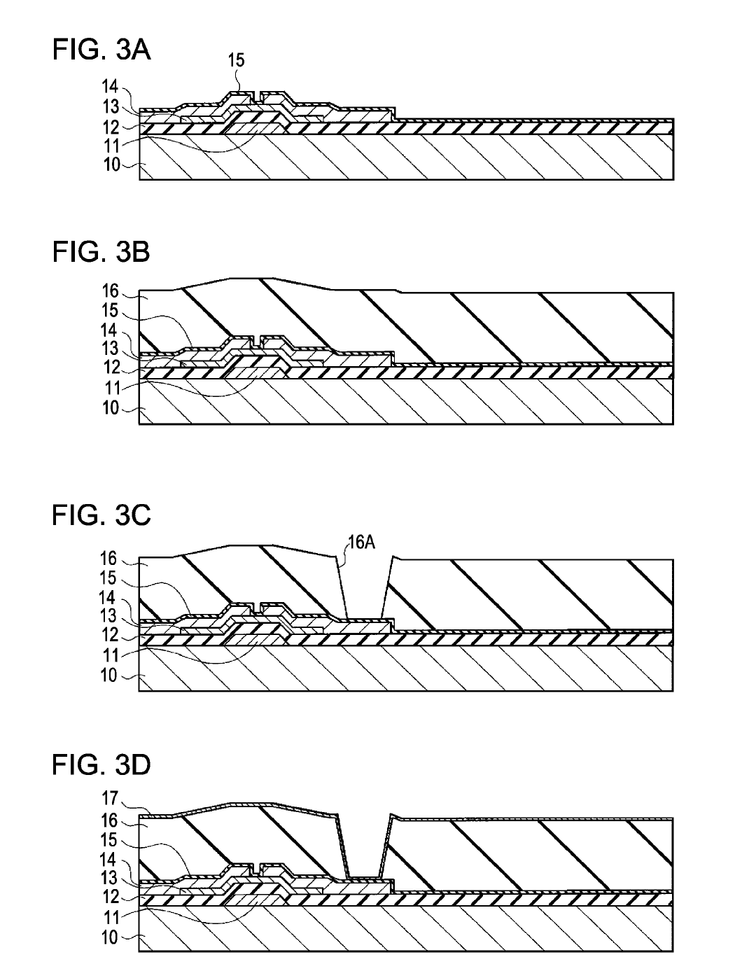

Next, as shown in FIGS. 3A and 3B, after the n+ a-Si layer (not shown) of the semiconductor layer 13 is etched, and the protective film 15 made of SiNx or the like is formed, the interlayer insulating film 16 made of SiNx or the like is formed. Subsequently, as shown in FIG. 3C, the interlayer insulating film 16 is patterned by a photolithographic method, so that the contact hole 16A is formed. Next, as shown in FIG. 3D, a surface treatment is performed on the surface of the interlayer insulating film 16 by a vapor phase method or a spin coating method using a silane coupling agent of the aforementioned material, so that the adhesive layer 17 is formed. In addition, in the case of a spin coating method, after a silane coupling agent diluted with a solvent is used for the treatment, heating may be performed, for example, at 120° C. for 5 minutes or more in the air. Furthermore, in the case of a vapor phase method, a silane coupling agent and the substrate 10 provided with TFTs formed thereon are placed in a chamber made of Teflon (registered trade name), followed by processing the whole chamber, for example, at 120° C. for approximately 12 hours. After a silane compound layer is formed on the substrate by a vapor phase method, in order to remove an excess silane compound, ultrasonic washing may be performed using a solvent, such as ethanol or isopropyl alcohol (IPA), followed by drying.

(3. Formation of the Reflection Electrode 5)

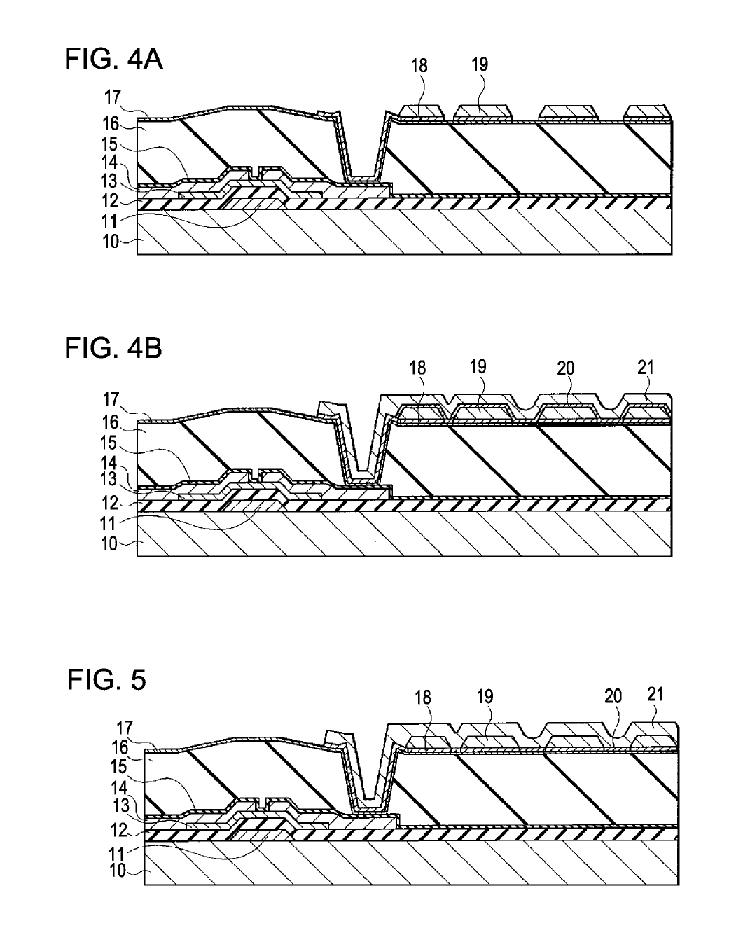

Next, as shown in FIG. 4A, the first catalytic layer 18 having a thickness of approximately several tens of nanometers is formed by patterning using an inversion offset method or the like and is then immersed in an electroless plating solution, so that the first plating layer 19 is formed. However, the patterning method is not limited to that described above, and various printing methods, such as a relief printing method, and patterning methods may be used as long as capable of forming a pattern at a position at which the first plating layer 19 is to be formed. As a plating solution, when nickel (Ni) is deposited as a plating layer, for example, a Ni—B film forming plating solution, BEL-801 (trade name), manufactured by C. Uyemura Co., Ltd. may be used. The temperature of a plating bath is set, for example, to 60° C., and the immersion time is appropriately determined in accordance with a desired thickness. In addition, the film forming rate is set, for example, to 100 nm/min.

Finally, as shown in FIG. 4B, the second plating layer 21 is formed. That is, first, as in the case of the first catalytic layer 18 described above, the second catalytic layer 20 is formed, for example, by an inversion offset method over the entire surface (on the first plating layer 19 and the adhesive layer 17) of the substrate 10. Next, by immersion in an electroless plating solution, the second plating layer 21 is formed on the second catalytic layer 20. Accordingly, the reflection electrode 5 having a concave-convex surface is formed. At this stage, it is preferable that after being warmed by hot water to a temperature approximately equal to that of the plating bath, the substrate 10 be immersed in the plating bath. As a result, the plating layer is prevented from being peeled away due to a stress of the plating layer thus formed. Incidentally, the pattern of the second catalytic layer 20 in this case is as shown, for example, in FIG. 8C.

After the drive substrate 1 including the reflection electrodes 5 is placed to face the counter substrate 2 and is sealed thereto which is additionally formed, the liquid crystal layer 3 is formed by injecting a liquid crystal between the drive substrate 1 and the counter substrate 2. As a result, the liquid crystal display device shown in FIG. 1 is obtained.

In this liquid crystal display device, light incident from the outside (surrounding environment) is efficiently reflected (diffuse-reflected) to a side of the liquid crystal layer 3 by the concave-convex portion of the reflection electrode 5 formed by the first plating layer 19 and the second plating layer 21, and as a result, a display can be performed.

### Second Embodiment

(Another Structural Example of the Reflection Electrode 5)

In the first embodiment described above, since the second catalytic layer 20 is formed on the first plating layer 19, depending on the thickness of the second catalytic layer 20, the type of electroless plating solution to be used, and the process conditions, the adhesion between the first plating layer 19 and the second plating layer 21 may be degraded in some cases.

In this embodiment, it is attempted to improve the adhesion between the first plating layer 19 and the second plating layer 21. Since the steps shown in FIGS. 2A to 4A of the first embodiment are similar to those of this second embodiment, a description thereof is omitted. In this embodiment, after the first plating layer 19 is formed on the first catalytic layer 18 as shown in FIG. 4A, the second catalytic layer 20 is formed on the adhesive layer 17 in the region (second region) other than the first region of the first catalytic layer 18 as shown in FIG. 5. That is, the second catalytic layer 20 is not formed on the first plating layer 19 but is formed only in the second region other than a region of the first plating 19. Accordingly, the first catalytic layer 18 and the second catalytic layer 20 are both in contact with the adhesive layer 17, and in addition, the second catalytic layer 20 is not provided between the first plating layer 19 and the second plating layer 21. As a result, the adhesion between the first plating layer 19 and the second plating layer 21 is improved.

When the pattern shape of the first catalytic layer 18 and that of the second catalytic layer 20 are controlled, and the film forming time of the first plating layer 19 and that of the second plating layer 21 are also controlled, the cross section of the reflection electrode 5 can be formed to have a desired shape. In addition, when a heat treatment is performed in a vacuum atmosphere, for example, at 200° C. after the second plating layer 21 is formed, the resistance thereof is decreased, and hence it can be used as an electrode. Furthermore, the second plating layer 21 is a so-called autocatalytic plating layer which is deposited using the first plating layer 19 as a catalyst.

Next, the operation and effect by the reflection electrode 5 and the formation method thereof will be described with reference to Comparative Examples 1 and 2.

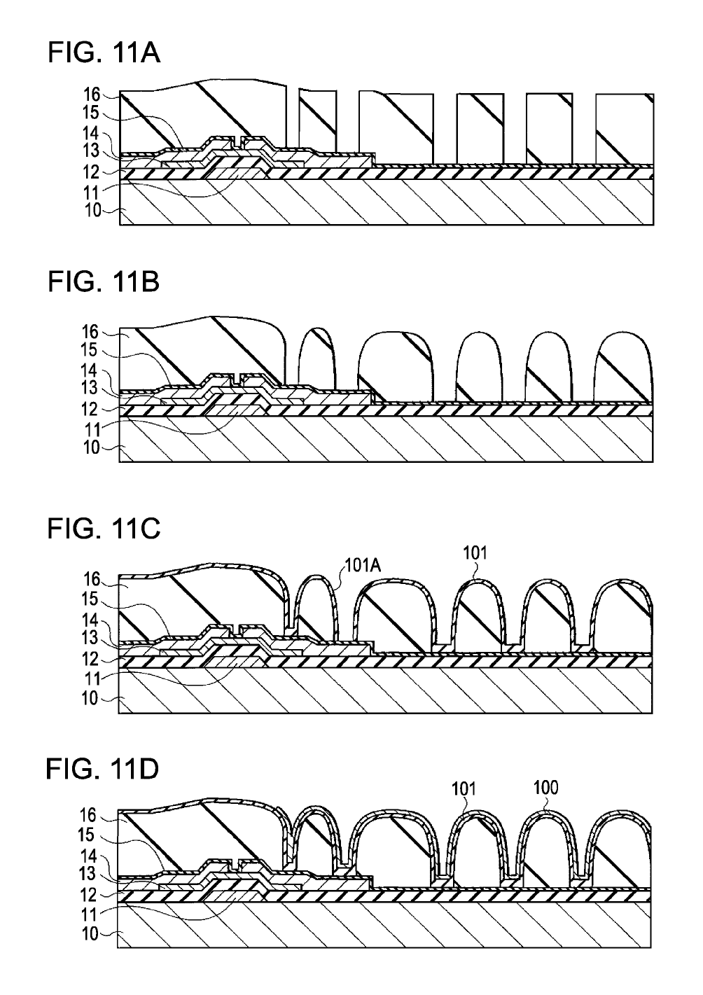

FIGS. 11A to 11D are cross-sectional views illustrating a formation method of a reflection electrode 100 according to Comparative Example 1. Since the same constituent elements as those of the above embodiment are designated by the same reference numerals as those described above, and the steps (FIGS. 2A to 3B) from the formation of the gate electrode 11 to that of the interlayer insulating film 16 of the above embodiment are similar to those of Comparative Example 1, a description thereof is omitted.

In Comparative Example 1, as shown in FIG. 11A, a photoresist film (not shown) is formed by application on the interlayer insulating film 16 formed in the step shown in FIG. 3B and is then selectively etched for patterning. Next, after the pattern is melted by a heat treatment as shown in FIG. 11B, a second interlayer insulating film 101 is further formed as shown in FIG. 11C, and a contact hole 101A is then formed. Subsequently, as shown in FIG. 11D, a metal film is formed on the second interlayer insulating film 101 by a vacuum deposition method or a sputtering method and is then patterned to form the reflection electrode 100.

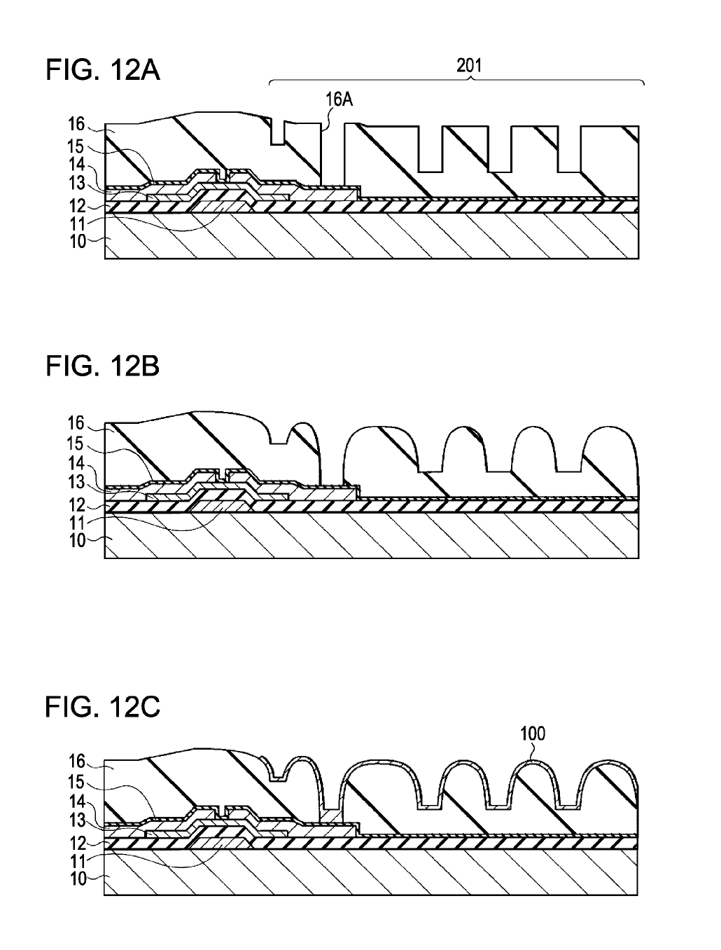

In Comparative Example 2, patterning of the interlayer insulating film 16 is performed by a photolithographic method using a half tone mask (or a two-stage exposure) as shown in FIGS. 12A to 12C. That is, in the interlayer insulating film 16, the contact hole 16A and concave-convex portion 201 having a different depth from that of the contact hole 16A are formed. The steps to be performed thereafter are similar to those of Comparative Example 1.

In the formation method of the reflection electrode 100 according to Comparative Examples 1 and 2, a step, such as etching, using a photoresist is necessarily performed two to three times, and hence the number of steps is unfavorably increased. In addition, since the photoresist is consumed in each photolithographic step, cost is disadvantageously increased.

On the other hand, in this embodiment, the first catalytic layer 18 is first formed in a predetermined region (first region) on the drive substrate 1 to form a plating layer, and a first electroless plating treatment is performed on this first catalytic layer 18, so that the first plating layer 19 is formed. Subsequently, the second catalytic layer 20 is formed at least in the region (second regions) other than the first region of the first catalytic layer 18, and a second electroless plating treatment is performed on the second catalytic layer 20, so that the second plating layer 21 is formed. As a result, the reflection electrode 5 having concave-convex surface can be formed in a desired region.

That is, in this embodiment, by the two-stage electroless plating treatment, the concave-convex shape of the reflection electrode 5 is formed without using an etching step or the like. Hence, compared to the case in which a photolithographic method is used as in Comparative Examples 1 and 2, a patterning step performed after the film formation is not necessary, and a reflection electrode having a concave-convex shape can be formed by simple steps. In addition, since the usage amount of a photosensitive resin (resist) can be reduced, cost can be reduced, and in addition, since an etching solution or an etching gas is not used, an environmental load can also be reduced.

In addition, in this embodiment, for example, when the thicknesses of the first catalytic layer 18, the second catalytic layer 20, the first plating layer 19, and the second plating layer 21 are appropriately selected, the reflection electrode 5 can be easily formed to have a desired concave-convex shape.

In this embodiment, although the Ni—B layers are formed as the first plating layer 19 and the second plating layer 21, when a metal layer, such as a Ag layer, having a higher optical reflectance is formed on the surface of the Ni—B layer, the reflectance of the reflection electrode 5 can be improved. Hereinafter, examples of the above case will be described.

### Third Embodiment

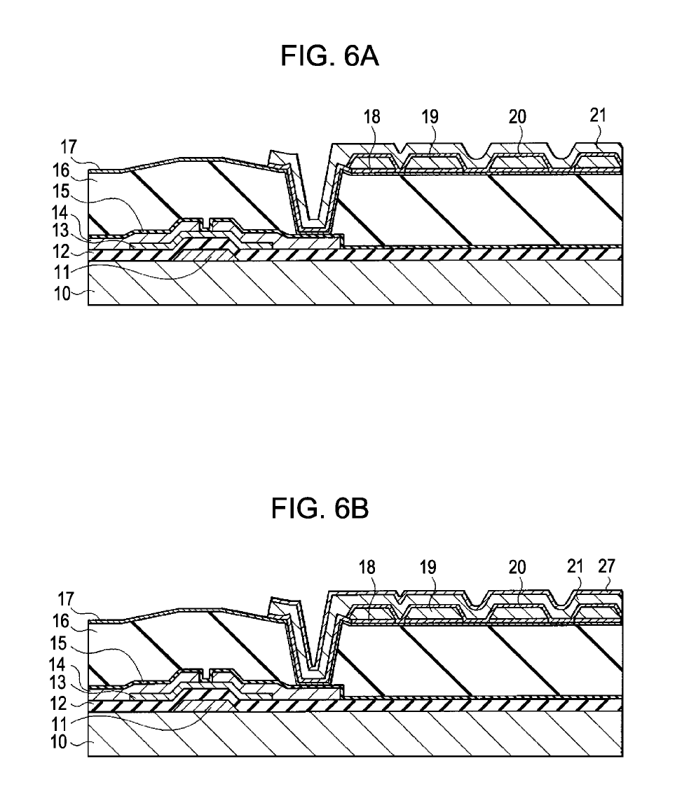

In this embodiment, as shown in FIG. 6B, a third plating layer 27 (Ag layer) is formed by electroless Ag plating on the second plating layer 21 (Ni—B layer) of the reflection electrode 5 shown in FIG. 6A (that is, shown in FIG. 4B of the first embodiment). The Ag plating can be performed using “Silver 7” manufactured by World Metals Corporation.

### Fourth Embodiment

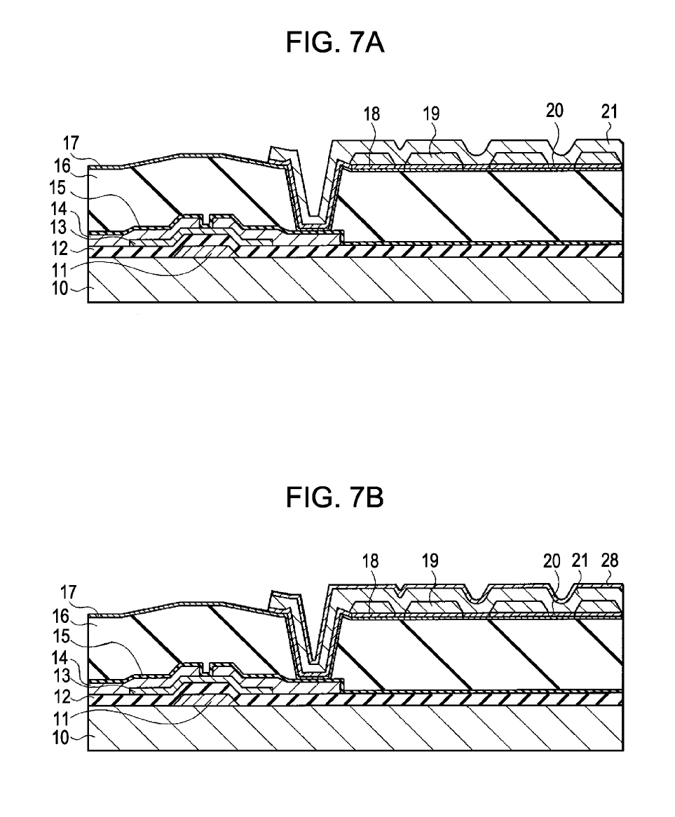

In this embodiment, as shown in FIG. 7B, a third plating layer 28 (Ag layer) is formed by electroless Ag plating on the second plating layer 21 (Ni—B layer) of the reflection electrode 5 shown in FIG. 7A (that is, shown in FIG. 5 of the second embodiment). The third plating layer 28 is formed in such a way that after the second plating layer 21 is formed, washing is performed with water, and the substrate is immersed in a silver-7 plating solution heated to 95° C. In addition, when the third plating layer 28 is formed, as a plating solution forming the second plating layer 21, for example, “Niboron MF”, which is a Ni—B plating solution, manufactured by World Metals Corporation may also be used.

### Example

Hereinafter, a particular example will be described.

First, a film of a metal (Cr) to be formed into the gate electrode 11 was formed on the substrate 10 by a sputtering method, and the gate electrode 11 was formed by patterning using a photolithographic method. Next, a film of a material (SiNx) to be formed into the gate insulating film 12 was formed, and as the semiconductor layer 13, an a-Si layer (channel) and an n+ a-Si layer to be formed into the contact layers (not shown) to be contact with the source/drain electrodes 14 were sequentially formed. Next, the semiconductor layer 13 thus formed was patterned by etching using a resist mask so as to have an island shape. Subsequently, a film of a metal (such as Al) to be formed into the source/drain electrodes 14 was formed by a vacuum process and was then patterned into a desired shape by etching using a resist mask, so that the source/drain electrodes 14 were formed. Next, after the n+ a-Si layer (not shown) formed on the a-Si layer was etched, the protective film 15 (SiNx) was formed, and the interlayer insulating film 16 was then formed thereon.

Next, after the interlayer insulating film 16 was patterned by a photolithographic method to form a concave portion at a place at which the contact hole 16A for a TFT was to be formed, a surface treatment was performed on the surface of the interlayer insulating film 16 by a spin coating method using a silane coupling agent of the aforementioned material, so that the adhesive layer 17 was formed. In this step, the silane coupling agent diluted by a solvent was used, and after the treatment was performed, heating was performed at 120° C. for 5 minutes or more. As an amino-based silane coupling agent to be formed into the adhesive layer 17, KBM-603 (trade name) manufactured by Shin-Etsu Chemical Co., Ltd. was used. In addition, after the silane compound layer was formed on the substrate by a vapor phase method, in order to remove an excess silane compound, ultrasonic washing was performed using a solvent, such as ethanol or isopropyl alcohol (IPA), followed by drying.

Next, the first catalytic layer 18 was formed from palladium fine particles used as a catalyst by patterning using an inversion offset method, and the substrate was then immersed in an electroless plating solution, so that the first plating layer 19 was formed. As the plating solution, a Ni—B film forming plating solution, BEL-801 (trade name), manufactured by C. Uyemura Co., Ltd. was used. When the temperature of the plating bath was set to 60° C., and the immersion was performed for 3 minutes, a Ni—B plating layer having a thickness of approximately 450 nm was formed. Subsequently, the second plating layer 21 was formed. First, as in the case of the first catalytic layer 18 described above, the second catalytic layer 20 is first formed on the first plating layer 19 and the adhesive layer 17 by an inversion offset method, and the substrate was then immersed in an electroless plating solution for 2 minutes, so that the second plating layer 21 having a thickness of approximately 200 nm was formed in a necessary region. By this process, the reflection electrode 5 was formed to have a step of approximately 450 nm between a concave and a convex portion. In addition, after the first plating layer 19 was formed, a heat treatment was performed at 200° C. in a vacuum atmosphere, so that the resistance of the first plating layer 19 was decreased.

Heretofore, although the present application has been described with reference to the first to the fourth embodiments and the example, the present application is not limited to those embodiments and the like and may also be variously modified. For example, when the contact characteristics with the source/drain electrodes 14 may cause a problem, without forming the adhesive layer 17, the plating layer may be directly formed on the interlayer insulating film 16.

In addition, in this embodiment, although the first plating layer 19 and the second plating layer 21 are formed from the same type of metal (such as Ni—B), they may be formed from metal materials different from each other. For example, the second plating layer 21 may be formed from Ag, and the first plating layer 19 may be formed from another metal (such as Ni).

In addition, in the above embodiments and the like, although the reflection type liquid crystal display device is described by way of example which performs a display using light reflected by the reflection electrode instead of illumination light emitted from a backlight, the display device according to an embodiment of the present application is not limited thereto. For example, the present application may also be applied to a so-called semi-transmissive liquid crystal display device which performs a display using both reflection light of outside light and illumination light emitted from a backlight, the backlight being provided at a rear side of a liquid crystal panel as well as reflection electrodes provided only in some regions of an effective display region.

Furthermore, the material and the thickness of each constituent element, and the film forming method and the conditions thereof, which are described in the above embodiments and the like, are not particularly limited; hence, another material and another thickness may also be selected, and another film forming method and other film forming conditions may also used.

It should be understood that various changes and modifications to the presently preferred embodiments described herein will be apparent to those skilled in the art. Such changes and modifications can be made without departing from the spirit and scope and without diminishing its intended advantages. It is therefore intended that such changes and modifications be covered by the appended claims.

1. A method for forming a reflection electrode comprising:
forming a first catalytic layer in a first region of an electrode forming region of a substrate;
forming a first plating layer on the first catalytic layer by performing a first electroless plating treatment;
forming a second catalytic layer at least in a region of the electrode forming region other than the first region; and
forming a second plating layer on the second catalytic layer by performing a second electroless plating treatment, so that the reflection electrode is formed to have a concave-convex surface.

2. The method for forming a reflection electrode according to claim 1, further comprising the steps of:
forming a drive element and an interlayer insulating film on the substrate in that order, and
forming a contact hole extending to the drive element in the interlayer insulating film,
wherein the reflection electrode is formed in a region including the inside of the contact hole and the upper surface of the interlayer insulating film.

3. The method for forming a reflection electrode according to claim 1,
wherein after the first plating layer is formed on the first catalytic layer, the second catalytic layer is formed over the entire surface of the electrode forming region, and the second electroless plating treatment is then performed.

4. The method for forming a reflection electrode according to claim 1,
wherein after the first plating layer is formed on the first catalytic layer, the second catalytic layer is formed only in the second region, and the second electroless plating treatment is then performed.

5. A drive substrate comprising:
a substrate which includes a reflection electrode having a concave-convex surface in an electrode forming region,
wherein the reflection electrode includes:
a first catalytic layer provided in a first region of the electrode forming region;
a first plating layer provided on the first catalytic layer;
a second catalytic layer provided at least in a region (second region) of the electrode forming region other than the first region; and
a second plating layer provided on the second catalytic layer.

6. The drive substrate according to claim 5, further comprising:
a drive element provided on the substrate; and
an interlayer insulating film provided on the drive element,
wherein the interlayer insulating film has a contact hole extending to the drive element, and
the reflection electrode is provided in a region including the inside of the contact hole and the upper surface of the interlayer insulating film.

7. A display device comprising:
a drive substrate which includes reflection electrodes each having a concave-convex surface in an electrode forming region; and
a display portion performing a display using incident light reflected by the reflection electrodes,
wherein the reflection electrodes each include:
a first catalytic layer provided in a first region of the electrode forming region;
a first plating layer provided on the first catalytic layer;
a second catalytic layer provided at least in a region (second region) of the electrode forming region other than the first region; and
a second plating layer provided on the second catalytic layer.

8. The display device according to claim 7,
wherein the display portion includes:
a counter substrate which is disposed to face the drive substrate and which has a transparent electrode; and
a liquid crystal layer provided between the drive substrate and the counter substrate.
